(19) United States
(12) Patent Application Publication
(10) Pub. No.: US 2019/0350084 A1
(43) Pub. Date: Nov. 14, 2019

(54) PRINTED CIRCUIT BOARD STRUCTURE AND METHOD OF FORMING THE SAME

(71) Applicant: Nan Ya Printed Circuit Board Corporation, Taoyuan City (TW)

(72) Inventors: Chin-Yi CHUANG, Taoyuan City (TW); Min-Huan KUO, Taoyuan City (TW); Chun-Chien LO, Taoyuan City (TW); Lung-Lin YU, Taoyuan City (TW)

(21) Appl. No.: 16/112,363

(22) Filed: Aug. 24, 2018

(30) Foreign Application Priority Data
May 11, 2018 (TW) 107116111

(51) Int. Cl. H05K 3/06; H05K 1/09; H05K 1/11; H05K 3/46

(52) U.S. Cl. CPC H05K 3/064; H05K 1/09; H05K 2201/09827; H05K 3/4644; H05K 1/115

(57) ABSTRACT

A printed circuit board structure includes a printed circuit board having a conductive structure, a dielectric structure and a copper foil layer. The copper foil layer has a first sub-copper foil layer and a second sub-copper foil layer on the printed circuit board. The dielectric structure and the first sub-copper foil layer have an opening. The opening exposes the conductive structure. A conductive bump is on the first sub-copper foil layer and in the opening, and the conductive bump is electrically connected to the conductive structure. A recess is between the first sub-copper foil layer and the second sub-copper foil layer, and the top surface of the second sub-copper foil layer is exposed. A method of forming the structure above is also provided.

### CROSS REFERENCE TO RELATED APPLICATION

This application claims priority of Taiwan Patent Application Serial No. 107116111 entitled “Printed circuit board structure and method of forming the same” and filed May, 11, 2018, the entire disclosure of which is hereby incorporated by reference.

### BACKGROUND

### Technical Field

The present disclosure relates to a printed circuit board structure and a method of forming the same.

### Description of the Related Art

Among the packaging techniques being used nowadays, highly effective electronic components are usually electrically and mechanically connected to each other through solder bumps. For example, an integrated circuit (IC) chip is usually bonded with a packaging substrate by solder bumps. This kind of bonding technique is also known as flip-chip (FC) bonding, which belongs to area array bonding. Thus, the technique is suited for use with high-density packaging connection processes.

In the process mentioned above, an electrode pad is disposed on the surface of an IC chip, and a packaging substrate has a corresponding electric contact pad. The IC chip is electrically connected to the packaging substrate via the solder bumps disposed on the electric contact pad of the packaging substrate. Generally, the electric contact pad of the packaging structure is a copper plating layer formed by electroplating. However, during electroplating, the distribution of the magnetic lines of force of the electroplating bath will result in an uneven thickness of the copper plating layer. Thus, the solder bumps cannot become coplanar when the solder bumps are disposed on to the copper plating layer. This will result in forming non-contact openings when the IC chip is subsequently bonded with the solder bumps, leading to bonding failure and further affecting the electrical connectivity between the IC chip and the packaging substrate.

Consequently, a new structure of a printed circuit board and a method of making it are currently needed in order to obtain a copper layer that serves as an electric contact pad with even thickness. This increases the coplanarity of the solder bumps disposed on the copper layer, and further improves the mechanical and electrical connectivity between the IC chip and the packaging substrate.

### SUMMARY

In accordance with some embodiments of the present disclosure, a printed circuit board structure is provided. A printed circuit board structure includes a printed circuit board having a conductive structure and a dielectric structure. A copper foil layer having a first sub-copper foil layer and a second sub-copper foil layer is on the printed circuit board, wherein the dielectric structure and the first sub-copper foil layer have an opening, and the opening exposes the conductive structure. There is a conductive bump on the first sub-copper foil layer and in the opening, wherein the conductive bump is connected to the conductive structure. There is a recess between the first sub-copper foil layer and the second sub-copper foil layer, and a top surface of the second sub-copper foil layer is exposed.

In accordance with some embodiments of the present disclosure, a method of forming a printed circuit board structure is provided. A method of forming a printed circuit board structure includes providing a printed circuit board having a conductive structure and a dielectric structure, forming a copper foil layer on the printed circuit board, and patterning the dielectric structure and the copper foil layer to form a first opening. The first opening exposes the conductive structure. A first photoresist layer is then disposed on the copper foil layer, and the first photoresist layer is patterned to form a second opening. Afterwards, a conductive bump is formed in the first opening and in the second opening, where the conductive bump is electrically connected to the conductive structure. The first photoresist layer is removed, and a patterned second photoresist layer is formed on the copper foil layer and the conductive bump. The copper foil layer is patterned into a first sub-copper foil layer, a second sub-copper foil layer and a recess by using the patterned second photoresist layer as a mask. The patterned second photoresist layer is removed to expose the top surface of the second sub-copper foil layer.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion. In the description and the figures that follow, unless additional explanation is provided, the same or like components will be represented using similar reference numerals.

FIGS. 1A to 1E are cross-sectional views of a printed circuit board structure of a comparative example at different stages.

FIGS. 2A to 2F are cross-sectional views of structures of a printed circuit board in accordance with some embodiments at different stages of the present invention.

### DETAILED DESCRIPTION

The following disclosure provides many different embodiments, or examples, for implementing different features of the subject matter provided. Specific examples of solutions and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. For simplicity and clarity, various features can be shown in different size arbitrarily.

Furthermore, spatially relative terms, such as “beneath,” “below,” “lower,” “above,” “upper” and the like, may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An embodiment according to the present disclosure provides a printed circuit board structure and a method of forming the same. Through performing selective electroplating process, a portion of a copper foil layer is exposed as a contact pad. Due to the better evenness of the thickness of the copper foil layer, the solder bumps disposed on the copper foil layer could obtain better coplanarity, and the mechanical and electrical connectivity between the IC chip and the packaging substrate may be further improved.

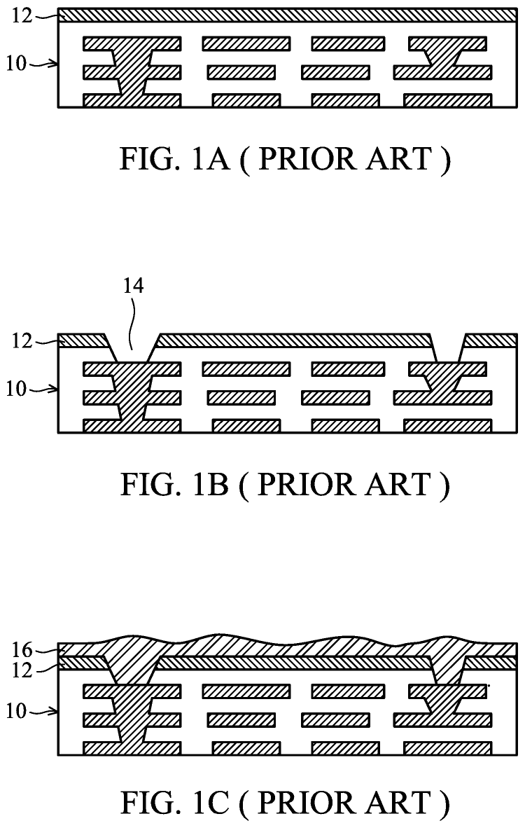

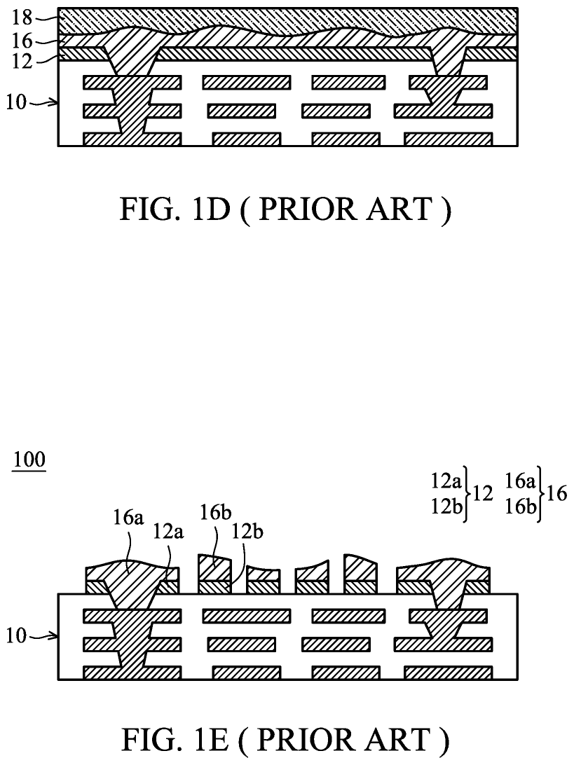

FIGS. 1A to 1E are cross-sectional views of a printed circuit board structure of a comparative example at different stages.

Referring to FIG. 1A, a printed circuit board 10 is provided and a copper foil layer 12 is formed on the printed circuit board 10. Referring to FIG. 1B, a portion of the copper foil layer 12 and a portion of a dielectric structure of the printed circuit board 10 are removed to form an opening 14. The opening 14 exposes a conductive structure of the printed circuit board 10.

Then, referring to FIG. 1C, a copper plating layer 16 is formed on the copper foil layer 12 and in the opening 14 completely by an electroplating process. Referring to FIGS. 1D to 1E, a photoresist layer 18 is disposed on the copper plating layer 16, and then the photoresist layer 18, the copper plating layer 16 and the copper foil layer 12 are patterned to form a sub-copper plating layer (copper bump) 16a, a sub-copper plating layer 16b, a sub-copper foil layer 12a and a sub-copper foil layer 12b. Finally, the photoresist layer 18 is removed. As shown in FIG. 1E, the sub-copper foil layer 12a and the sub-copper foil layer 12b are covered by the copper bump 16a and the sub-copper plating layer 16b respectively, and the sub-copper plating layer 16b serves as a contact pad for disposing solder bumps afterwards.

In the comparative example mentioned above, as shown in FIG. 1C and FIG. 1E, during the electroplating process, the copper plating layer 16 is formed on the copper foil layer 12 and in the opening 14 completely. However, the distribution of the magnetic lines of force of the electroplating bath results in the uneven thickness of the copper plating layer 16. Therefore, the sub-copper plating layer 16b formed subsequently also has uneven thickness with a height difference. Consequently, in subsequent fabricating process, when solder bumps are disposed on to the sub-copper layer 16b, these solder bumps may not become coplanar. When an IC chip is bonded with the solder bumps, a non-contact opening will be formed. The non-contact opening deteriorates the mechanical connectivity and further affects the electrical connectivity between the IC chip and the printed circuit board structure 100.

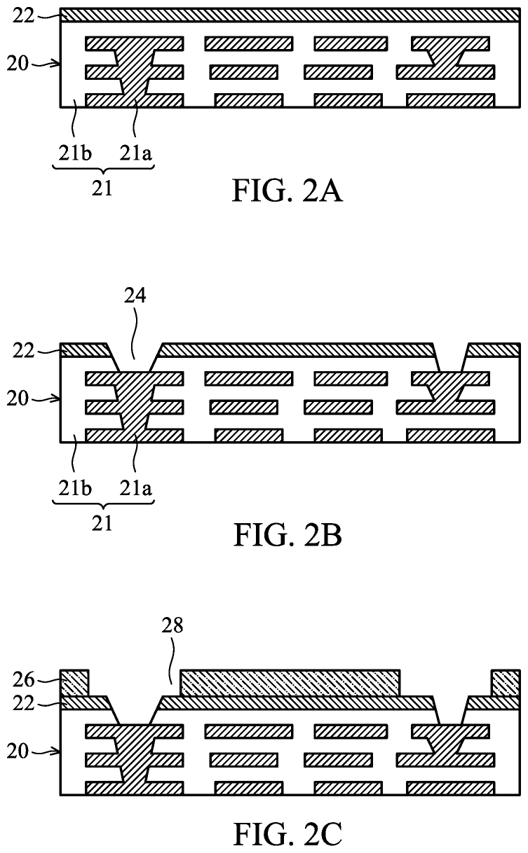

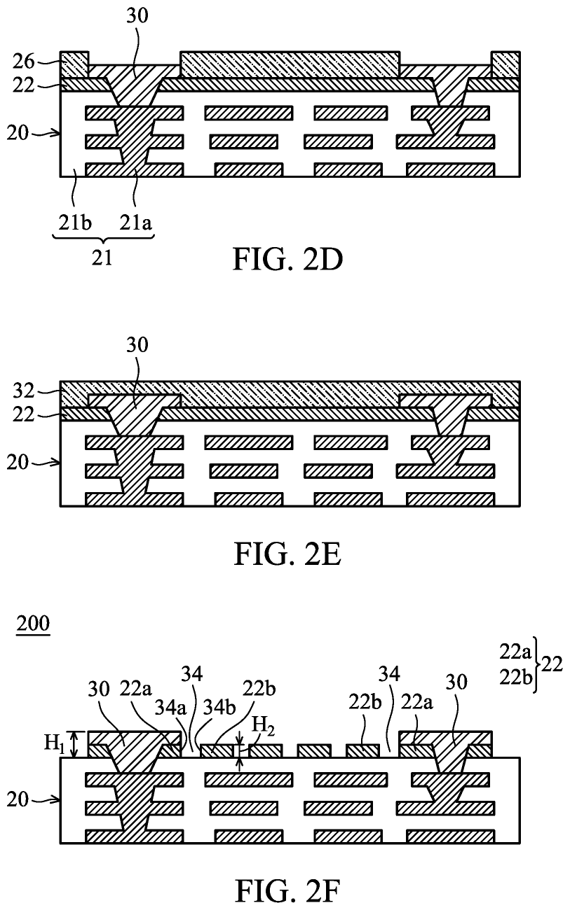

FIGS. 2A to 2F are cross-sectional views of a printed circuit board structure in accordance with some embodiments of the present invention at different stages.

Referring to FIG. 2A, a printed circuit board 20 is provided, and a copper foil layer 22 is formed on the printed circuit board 20. The printed circuit board 20 includes a substrate (not shown) and a circuit structure 21 formed on the substrate. The circuit structure 21 includes a conductive structure 21a and a dielectric structure 21b. In some embodiments, the substrate may be a core board. The material of the substrate may include paper phenolic resin, composite epoxy resin, polyimide resin, glass fiber or other suitable materials as known in the art for core board. In some embodiments, the conductive structure 21a may be a single layer or multiple layers. The material of the conductive structure 21a may include nickel, gold, tin, lead, copper, aluminum, silver, chromium, tungsten, or any combinations or alloys thereof. The method of forming the conductive structure 21a may include exposure process, development process, etching process, deposition process, electroplating process, lamination process, coating process or any combinations thereof. In some embodiments, the material of the dielectric structure 21b may be epoxy resin, bismaleimide-triazine (BT) resin, polyimide (PI), Ajinomoto build-up film, poly phenylene oxide (PPO), polypropylene (PP), polymethylmethacrylate (PMMA), polytetrafluorethylene (PTFE), or any other suitable dielectric material. The method of forming the dielectric structure 21b may include deposition process, lamination process, coating process or any combinations thereof. In some embodiments, the material of the copper foil layer 22 may include copper, or an alloy made from copper and at least one of zinc, tin, cobalt, nickel, chrome and molybdenum, or other material alike. The method of forming the copper foil layer 22 may include electroplating process, electroless plating process, sputtering process, chemical vapor deposition process, or any combination thereof.

Referring to FIG. 2B, the copper foil layer 22 and the dielectric structure 21b are patterned so as to remove a portion of the copper foil layer 22 and the dielectric structure 21b, forming an opening 24 which exposes the conductive structure 21a. After that, referring to FIG. 2C, a photoresist layer (which is also called as a dry film) 26 is disposed on the copper foil layer 22, and then the photoresist layer 26 is patterned to form an opening 28. The opening 28 exposes the opening 24 and a portion of the copper foil layer 22. In some embodiments, the photoresist layer 26 may include one or more photosensitive materials. For instance, the photoresist layer 26 may include a material that is sensitive to ultraviolet (UV), deep ultraviolet (DUV) and/or extreme ultraviolet (EUV) light. The photoresist layer 26 may be formed by a spin coating process or any other suitable process. In some embodiments, the method of the patterning may include exposure, development, etching, a laser process, or any combination thereof.

Afterwards, referring to FIG. 2D, a copper bump 30 is formed in the opening 24 and the opening 28 by the electroplating process. The copper bumps 30 are electrically connected to the conductive structure 21a. As shown in FIG. 2D, in some embodiments, the photoresist layer 26 is directly in contacts with the copper foil layer 22. Sidewalls of the copper bumps 30 are adjacent to sidewalls of the photoresist layer 26, and top surfaces of the copper bumps 30 is lower than a top surface of the photoresist layer 26.

It should be noted that due to a portion of the copper foil layer 22 being covered by the photoresist layer 26, the copper plating layer (copper bumps) 30 may be selectively formed only in opening 24 and opening 28 during the electroplating process. The copper foil layer 22 that is shielded by the photoresist layer 26 does not have a copper plating layer. The copper foil layer 22 that is shielded by the photoresist layer 26 will afterwards become a contact pad (which is also known as an edge connector).

Referring to FIG. 2E, after removing the photoresist layer 26, a photoresist layer 32 is disposed on the copper foil layer 22 and the copper bumps 30, and then the photoresist layer 32 is patterned. Subsequently, the copper foil layer 22 is patterned by using the patterned photoresist layer 32 as a mask so as to transform the copper foil layer 22 into the sub-copper foil layer 22a, the sub-copper foil layer 22b, and recesses 34. In the meantime, the patterned photoresist layer 32 contacts the sub-copper foil layer 22b directly. In the end, as shown in FIG. 2F, the photoresist layer 32 is removed to expose the top surface of the sub-copper foil layer 22b. The top surface of the sub-copper foil layer 22b serves as a contact pad. The top surface of the sub-copper foil layer 22a is covered by the copper bumps 30.

In some embodiments, various suitable etching and/or stripping processes may be used, such as dry etching, wet etching, and/or other etching process (e.g. reactive ion etching (RIE), chemical mechanical polishing/planarization (CMP), etc.) to remove the photoresist layer 26/32. In some embodiments, the photoresist layer 32 may include one or more photosensitive materials. For example, the photoresist layer 32 may include a photoresist material that is sensitive to ultraviolet (UV), deep ultraviolet (DUV) and/or extreme ultraviolet (EUV) light. The photoresist layer 32 may be formed by a spin coating process or any other suitable process. In some embodiments, the method of patterning may include exposure, development, etching, a laser process, or any combination thereof.

As shown in FIG. 2F, the recesses 34 are between the sub-copper foil layer 22a and the sub-copper foil layer 22b. In some embodiments, the recess 34 has a sidewall 34a and a sidewall 34b. The sidewall 34a and the sidewall 34b face each other. The sidewall 34a and the sidewall 34b are different heights. Furthermore, the sidewall 34a has a height H₁ and the sidewall 34b has a height H₂. The height H₁ is greater than the height H₂. In some embodiments, the difference between height H₁ and height H₂ is a thickness of the copper bump 30 on the sub-copper foil layer 22a. In some embodiments, the sidewall 34a is the sidewall of the sub-copper foil layer 22a and the copper bumps 30, and the sidewall 34b is the sidewall of the sub-copper foil layer 22b.

It should be noted that, during the process mentioned above, the area that is designed to form the copper foil layer 22b is covered by the photoresist layer 26 so the area does not have a copper plating layer. Thereby the top surface of the copper foil layer 22b can be exposed to serve as contact pads. Moreover, since the copper foil layer has better evenness of the copper thickness, the problem of the unevenness of the copper plating layer resulting from the distribution of the magnetic lines of force of the electroplating bath in the prior art may be avoided. By that means, the coplanarity of the solder bumps disposed on the sub-copper layer 22b in the subsequent processes may be further increased. The mechanical and the electrical connectivity between an IC chip and a printed circuit board 200 may be improved as well.

To sum up, the embodiments in this disclosure provide a printed circuit board structure and a method of forming the same. By selective electroplating, a portion of a copper foil layer is exposed to serve as contact pads. Since the copper foil layer has better evenness of the copper thickness, the coplanarity of the solder bumps disposed on the copper foil layer can be increased, and the mechanical and the electrical connectivity between an IC chip and a printed circuit board may be further improved.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

1. A printed circuit board structure, comprising:
a printed circuit board having a conductive structure and a dielectric structure;
a copper foil layer having a first sub-copper foil layer and a second sub-copper foil layer on the printed circuit board, wherein the dielectric structure and the first sub-copper foil layer have an opening that exposes the conductive structure; and
a conductive bump on the first sub-copper foil layer and in the opening, wherein the conductive bump is electrically connected to the conductive structure; and
a recess between the first sub-copper foil layer and the second sub-copper foil layer, wherein a top surface of the second sub-copper foil layer is exposed.

2. The printed circuit board structure as claimed in claim 1, wherein the recess has a first sidewall and a second sidewall opposite to the first sidewall, and a height of the first sidewall is different from a height of the second sidewall.

3. The printed circuit board structure as claimed in claim 2, wherein the height of the first sidewall is greater than the height of the second sidewall, and a height difference between the first sidewall and the second sidewall is a thickness of the conductive bump on the first sub-copper foil layer.

4. The printed circuit board structure as claimed in claim 2, wherein the first sidewall is a sidewall of the first sub-copper foil layer and the conductive bump; the second sidewall is a sidewall of the second sub-copper foil layer.

5. A method of forming the printed circuit board structure as claimed in claim 1, comprising:
providing the printed circuit board having the conductive structure and the dielectric structure;
forming the copper foil layer on the printed circuit board;
patterning the dielectric structure and the copper foil layer to form a first opening that exposes the conductive structure;
disposing a first photoresist layer on the copper foil layer and then patterning the first photoresist layer to form a second opening;
forming the conductive bump in the first opening and in the second opening, wherein the conductive bump is electrically connected to the conductive structure;
removing the first photoresist layer;
forming a patterned second photoresist layer on the copper foil layer and the conductive bump;
patterning the copper foil layer into the first sub-copper foil layer, the second sub-copper foil layer and the recess by using the patterned second photoresist layer as a mask; and
removing the patterned second photoresist layer to expose the top surface of the second sub-copper foil layer.

6. The method of forming a printed circuit board structure as claimed in claim 5, wherein a top surface of the first sub-copper foil layer is covered by the conductive bump.

7. The method of forming a printed circuit board structure as claimed in claim 5, wherein the second opening exposes the first opening and a portion of the copper foil layer.

8. The method of forming a printed circuit board structure as claimed in claim 5, wherein the first photoresist layer directly contacts the copper foil layer before removing the first photoresist layer.

9. The method of forming a printed circuit board structure as claimed in claim 5, wherein a sidewall of the conductive bump is adjacent to a sidewall of the first photoresist layer before removing the first photoresist layer.

10. The method of forming a printed circuit board structure as claimed in claim 5, wherein a top surface of the conductive bump is lower than a top surface of the first photoresist layer before removing the first photoresist layer.

11. The method of forming a printed circuit board structure as claimed in claim 5, wherein the second photoresist layer directly contacts the second sub-copper foil layer before removing the second photoresist layer.

12. The printed circuit board structure as claimed in claim 1, wherein the conductive bump penetrates the first sub-copper foil layer and directly contacts the conductive structure.

13. The method of forming a printed circuit board structure as claimed in claim 5, wherein the conductive bump penetrates the first sub-copper foil layer and directly contacts the conductive structure.
